(19) United States
(12) Patent Application Publication
(10) Pub. No.: US 2011/0127614 A1
(43) Pub. Date: Jun. 2, 2011

(54) REDUCING THE SERIES RESISTANCE IN SOPHISTICATED TRANSISTORS BY EMBEDDING METAL SILICIDE CONTACT REGIONS RELIABLY INTO HIGHLY DOPED SEMICONDUCTOR MATERIAL

(76) Inventors: Thilo Scheiper, Dresden (DE); Sven Beyer, Dresden (DE); Jan Hoentschel, Dresden (DE); Uwe Griebenow, Markkleeberg (DE)

(21) Appl. No.: 12/905,545

(22) Filed: Oct. 15, 2010

(30) Foreign Application Priority Data
Nov. 30, 2009 (DE) 10200947308.4

(51) Int. Cl. H01L 27/092; H01L 21/336; H01L 21/8238

(52) U.S. Cl. 257/369; 438/301; 438/230; 257/E21.409; 257/E21.632; 257/E27.062

(57) ABSTRACT

In sophisticated transistor elements, an additional silicon-containing semiconductor material may be provided after forming the drain and source extension regions, thereby reducing the probability of forming metal silicide regions, such as nickel silicide regions, which may extend into the channel region, thereby causing a significant increase in series resistance. Consequently, an increased degree of flexibility in adjusting the overall transistor characteristics may be achieved, for instance, by selecting a reduced spacer width and the like.

### BACKGROUND OF THE INVENTION

1. Field of the Invention

The present disclosure generally relates to the fabrication of integrated circuits, and, more particularly, to the fabrication of highly sophisticated field effect transistors, such as MOS transistor structures, requiring highly doped shallow junctions and a low series resistance.

2. Description of the Related Art

The manufacturing process for integrated circuits continues to improve in several ways, driven by the ongoing efforts to scale down the feature sizes of the individual circuit elements. Presently, and in the foreseeable future, the majority of integrated circuits are, and will be, based on silicon devices due to the high availability of silicon substrates and due to the well-established process technology that has been developed over the past decades. A key issue in developing integrated circuits of increased packing density and enhanced performance is the scaling of transistor elements, such as MOS transistor elements, to provide the immense number of transistor elements that may be necessary for producing complex integrated circuits, such as CPUs, memory devices, mixed signal devices and the like. One important aspect in manufacturing field effect transistors having reduced dimensions is the reduction of the length of the gate electrode that controls the formation of a conductive channel separating the source and drain regions of the transistor. The source and drain regions of the transistor element are conductive semiconductor regions including dopants of an inverse conductivity type compared to the dopants in the surrounding crystalline active region, e.g., a substrate or a well region.

Although the reduction of the gate length results in smaller and faster transistor elements, it turns out, however, that a plurality of issues are additionally involved to maintain proper transistor performance for a reduced gate length. One challenging task in this respect is the provision of shallow junction regions, i.e., source and drain extension regions and drain and source regions connecting thereto, which nevertheless exhibit a high conductivity so as to minimize the resistivity in conducting charge carriers from the source via the channel and to the drain region.

Consequently, sophisticated implantation techniques are typically applied in order to form very shallow yet moderately highly doped drain and source extension regions with a desired minimal lateral offset to the channel region, which is typically accomplished on the basis of appropriate offset spacer elements formed on that gate electrode structure. Further-more, in order to adjust transistor characteristics, typically, counter-doped regions or halo regions may be provided adjacent to the drain and source extension regions and adjacent to the channel region, which may require tilted implantation processes. Thereafter, the drain and source regions may be formed on the basis of an increased lateral offset obtained by a corresponding sidewall spacer structure, wherein, typically, a high concentration of the drain and source dopant species is incorporated so as to appropriately connect to the drain and source extension regions. Depending on the complexity of the lateral and vertical dopant profiles, additional implantation processes may be required to obtain the desired transition in dopant concentration from the extremely shallow source and drain extension regions to the actual drain and source regions.

In an attempt to further reduce the overall series resistance of the current path in the transistor devices, in addition to reducing the channel length, the resistance of portions of the drain and source regions is also lowered by incorporating a metal silicide, which may typically exhibit a lower sheet resistance compared to silicon, even if highly doped. In sophisticated approaches, nickel as a refractory metal is frequently used for locally increasing the conductivity of doped silicon areas due to the moderately low resistance of nickel silicide compared to other metal silicide materials. Hence, nickel silicide is formed in surface areas of the drain and source regions and possibly in gate electrode structures to provide superior conductivity in these areas. Upon further reducing the overall transistor dimensions, which may typically be associated with reducing the depth of drain and source regions, the process of forming a nickel silicide may have to be precisely controlled in order to avoid irregularities or even an increase in series resistance of advanced transistors, as will be explained in more detail with reference to FIGS. 1a-1b.

FIG. 1a schematically illustrates a cross-sectional view of a semiconductor device 100 comprising a transistor 150A, which, in the example shown, represents an N-channel transistor. The transistor 150A is formed in and above an active region 102A, which in turn represents a portion of a silicon-based semiconductor layer 102. Moreover, the semiconductor layer 102 is formed above a substrate 101, such as a silicon substrate and the like. The transistor 150A further comprises a dopant profile in the active region 102A in order to provide drain and source extension regions 156D, 156S, which laterally enclose a channel region 155. The drain and source extension regions 156D, 156S represent N-doped areas, while the channel region 155 may represent a P-doped portion of the active region 102A. Moreover, drain and source regions 157D, 157S are provided with a desired high dopant concentration and connect to the corresponding extension regions 156D, 156S, respectively. Furthermore, the transistor 150A comprises a gate electrode 151, which is separated from the channel region 155 by a gate dielectric material 152. The gate electrode 151 may be comprised of any appropriate material, such as a metal and the like. Similarly, the gate dielectric material 152 may be comprised of any appropriate dielectric material, such as silicon oxynitride, possibly in combination with a high-k dielectric material, and the like. Furthermore, an offset spacer element 153, such as a silicon dioxide spacer, a silicon nitride spacer and the like, or a combination thereof, is provided on sidewalls of the gate electrode 151. Additionally, a spacer structure 154 is formed on the offset spacer 153 and, as discussed above, nickel silicide areas 158 are provided in the drain and source regions 157D, 157S in order to increase the conductivity of the transistor 150A. Furthermore, the transistor 150A is embedded in an interlayer dielectric material 110, which may comprise two or more different materials, such as a layer 111, such as a silicon nitride layer, and a silicon dioxide layer 112. Moreover, a contact element 113 is provided in the interlayer dielectric material 110 and is illustrated so as to connect to the nickel silicide region 158 in the source region 157S.

The semiconductor device 100 as illustrated in FIG. 1a may be formed on the basis of any appropriate process strategies. For instance, the active region 102A may be formed by providing appropriate isolation structures (not shown) in the semiconductor layer 102 so as to laterally delineate the active region 102A, which may, prior to or after forming the isolation structures, receive an appropriate dopant concentration in order to adjust the basic transistor characteristics. Thereafter, the gate dielectric material 152 and the gate electrode 151 are formed on the basis of sophisticated deposition and patterning techniques which strongly depend on the type of materials to be used in the gate dielectric material 152 and the electrode 151. Next, the offset spacer element 153 may be formed by oxidation and/or deposition in combination with etch techniques, followed by sophisticated implantation processes in order to form the drain and source extension regions 156D, 156S. Moreover, as explained above, additional dopant species may be incorporated into the active region 102A based on a dopant species providing the inverse conductivity type compared to the drain and source dopant species. Thereafter, the sidewall spacer structure 154 may be formed by depositing one or more appropriate material layers, such as silicon dioxide in combination with silicon nitride, and patterning the layer stack to obtain the structure 154. The spacer structure 154 is formed so as to act as an implantation mask and also to adjust an offset of the metal silicide regions 158 from the PN junctions of the drain and source regions 157D, 157S. After forming the spacer structure 154, implantation processes may be performed to incorporate a high concentration of the drain and source dopant species and to appropriately connect to the previously formed drain and source extension regions 156D, 156S. After annealing the transistor 150A in order to establish the final dopant profile by activating the dopant, re-crystallizing implantation-induced damage and initiating a certain degree of dopant diffusion, if required, the nickel silicide regions 158 are formed by depositing a nickel layer and initiating a chemical reaction, wherein the diffusion behavior of nickel and silicon may strongly depend on the overall process parameters, such as temperature, crystalline state of the silicon material, dopant concentration and the like. Next, the interlayer dielectric material 110 is formed by depositing the material 111 and the material 112 and patterning these materials in order to provide a contact opening, which may subsequently be filled with an appropriate conductive material, such as tungsten and the like, thereby forming the contact element 113.

During operation of the transistor 150A, the gate electrode 151 may receive an appropriate control voltage to build up an electron channel 155E in the channel region 155, thereby enabling a current flow, i.e., an electron flow, from the contact element 113 into the nickel silicide region 158 and into the source region 157S. Consequently, via the extension region 156S and the source region 157S, electrons may reach the channel region 155 and may thus build up the electron channel 155E, wherein the corresponding resistivity depends on the resistance of the various individual portions of the entire conductive path from the contact element 113 into the channel region 155.

It is well known that nickel silicide forms a Schottky barrier with a doped silicon material, which results in a high resistance for a transition of electrons from the nickel silicide into the surrounding doped silicon material. By heavily doping the silicon material, the barrier may be significantly reduced by reducing a corresponding depletion zone, thereby finally obtaining an ohmic behavior with a very low resistance. Consequently, in the ideal situation, as shown in FIG. 1a, a low series resistance is obtained, since the nickel silicide region 158 is completely surrounded by a highly doped silicon material, thereby providing a low ohmic resistance, which thus directly translates into superior performance of the transistor 150A.

As indicated above, upon further reducing the overall device dimensions, for instance by reducing a gate length to 50 nm and less, other dimensions, such as the width of the spacer elements and the like, are also to be adapted to the desired critical dimensions, thereby, however, contributing to an increased probability of creating failures in the nickel silicide regions.

FIG. 1b schematically illustrates the semiconductor device 100, in which the metal silicide region 158 in the source region 157S may extend into the channel region 155, thereby “shorting” the PN junction. For example, upon forming the nickel silicide regions 158, a desired reduction in spacer width of the spacer structure 153 may have resulted in undue nickel diffusion into the channel region 155, thereby forming a portion 158R of nickel silicide that is positioned within the channel region 155. For example, a reduction of spacer width may be advantageous, for instance, in view of appropriately connecting the drain and source regions 157D, 157S to the corresponding extension regions, while, in other cases, further performance improving mechanisms, such as providing one or more materials of interlayer dielectric material 110 with a high internal stress level, may be applied, in which case a reduced offset of the highly stressed dielectric material from the channel region is advantageous.

As discussed above, since the portion 158R is surrounded by silicon material of a significantly reduced degree of doping, a Schottky barrier may exist at the interface to the channel region 155, thereby significantly increasing the resistance of the portion 158R. Consequently, upon operating the device 150A in the on state, the portion 158R may not substantially contribute to the overall electron flow, thereby significantly increasing the resulting overall series resistance, which may thus compromise the DC behavior of the transistor 150A. Consequently, in advanced conventional strategies, appropriate process margins may have to be implemented to reduce the probability of creating irregularities of the metal silicide regions, such as extension of these regions into the channel regions, for instance by providing spacer elements of increased width and the like, which in turn may, however, negatively influence the overall performance of the transistor 150A, for instance in terms of switching speed and the like.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and manufacturing techniques in which a metal silicide, such as nickel silicide, may be efficiently embedded in a highly doped silicon or semiconductor material by forming additional semiconductor material adjacent to the gate electrode structure of at least one type of transistors, such as N-channel transistors, after forming the drain and source extension regions. For this purpose, selective epitaxial growth techniques may be applied to form additional semiconductor material, for instance, prior to the formation of a sidewall spacer structure or after the formation of the sidewall spacer structure, wherein a desired high dopant concentration may be obtained, for instance, on the basis of the regular drain and source implantation process and/or by incorporating a drain and source dopant species during the deposition of the additional semiconductor material. The deposition of a highly doped additional semiconductor material may be accomplished by using an appropriate masking regime in order to provide highly N-doped semiconductor material for N-channel transistors and/or highly P-doped semiconductor material for P-channel transistors. In some illustrative aspects disclosed herein, the deposition of the additional semiconductor material, for instance in the form of a highly doped material, may be restricted to a desired transistor type without using a deposition mask by exploiting the self-limiting deposition behavior of specific crystallographic planes of the underlying semiconductor material in one type of transistor.

One illustrative method disclosed herein comprises forming drain and source extension regions in a semiconductor region by using a gate electrode structure as an implantation mask. The method further comprises forming a silicon-containing semiconductor material above the drain and source extension regions on the semiconductor region laterally adjacent to the gate electrode structure. Additionally, the method comprises forming drain and source regions in at least a portion of the silicon-containing semiconductor material and forming a metal silicide in the silicon-containing semiconductor material.

A further illustrative method disclosed herein comprises forming a first gate electrode structure of a P-channel transistor above a first active region. The method additionally comprises forming a second gate electrode structure of an N-channel transistor above a second active region. Moreover, drain and source regions are formed in the first and second active regions. The method further comprises forming a silicon-containing semiconductor material above the drain and source extension regions of at least one of the P-channel transistor and the N-channel transistor. Moreover, drain and source regions of the P-channel transistor and the N-channel transistor are formed. Furthermore, the method comprises forming a metal silicide at least in a portion of the silicon-containing semiconductor material.

One illustrative semiconductor device disclosed herein comprises a P-channel transistor formed in and above a first active region and an N-channel transistor formed in and above a second active region. The semiconductor device further comprises a doped silicon-containing semiconductor material formed on the second active region so as to provide a raised drain and source configuration. Moreover, a nickel silicide is embedded in the doped silicon-containing semiconductor material.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a transistor in cross-sectional view, in which, ideally, the nickel silicide material is embedded in a highly doped drain and source area, according to a conventional planar transistor architecture;

FIG. 1b schematically illustrates the transistor with reduced critical dimensions, wherein the nickel silicide may penetrate the channel region, according to conventional device architectures;

FIGS. 2a-2e schematically illustrate cross-sectional views of a semiconductor device during various manufacturing stages, in which a raised drain and source configuration may be provided after forming the drain and source extension regions and halo regions on the basis of a spacer structure including offset spacers prior to forming an additional sidewall spacer structure, according to illustrative embodiments;

FIGS. 2f-2h schematically illustrate cross-sectional views of the semiconductor device according to illustrative embodiments in which the raised drain and source configuration may be formed after providing a sidewall spacer structure used for laterally offsetting drain and source regions;

FIGS. 2i-2k schematically illustrate cross-sectional views of the semiconductor device according to illustrative embodiments in which a raised drain and source configuration may be obtained after forming the main spacer structure on the basis of a masking regime so as to selectively provide a highly doped semiconductor material for different types of transistors;

FIGS. 2l-2m schematically illustrate cross-sectional views of the semiconductor device according to illustrative embodiments in which the drain and source regions of at least one type of transistor may be formed on the basis of a doped semiconductor material deposited prior to forming the main spacer structure; and

FIGS. 2n-2r schematically illustrate cross-sectional views of the semiconductor device according to still further illustrative embodiments in which the additional semiconductor material may be provided in a selective manner without using a hard mask material.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally provides semiconductor devices and manufacturing techniques in which a raised drain and source configuration may be provided by growing an additional silicon-containing semiconductor material on the active regions of at least one type of transistor after forming therein drain and source extension regions and halo regions. For this purpose, selective epitaxial growth techniques may be applied in order to provide the additional silicon-containing semiconductor material in a substantially non-doped configuration or in a highly doped configuration, depending on the overall process strategy. For example, in some illustrative embodiments, the additional silicon-containing semiconductor material may be grown commonly on active regions of N-channel transistors and P-channel transistors as a substantially non-doped semiconductor material, for instance prior to forming a corresponding sidewall spacer structure or after forming a sidewall spacer structure, wherein the drain and source dopant species may be incorporated on the basis of ion implantation processes, thereby also providing a desired high dopant concentration in the additional silicon-containing semiconductor material. Consequently, during further processing, the metal silicide, for instance the nickel silicide, may be formed in a portion of the additional semiconductor material, thereby reducing the probability of creating silicide defects, for instance in the form of silicide portions extending into the channel region. Consequently, an increased degree of flexibility in designing spacer structures may be accomplished, since the additional semiconductor material may provide superior process margins during the silicidation process.

In still other illustrative embodiments disclosed herein, the additional silicon-containing semiconductor material may be provided in a selective manner in the form of a highly doped material, which may be accomplished by masking one transistor by a hard mask material, while growing the semiconductor material on another transistor while incorporating a desired type of dopant species. If desired, a similar masking regime may be applied so as to cover the transistor having received the additional semiconductor material in order to selectively grow the additional semiconductor material on the previously-masked transistor, thereby enabling the incorporation of the desired type of dopant species. The selective growth of the additional semiconductor material may also be applied prior to or after the formation of the main spacer structure, depending on the overall process strategy. For example, the drain and source regions may be efficiently provided in the form of the doped additional semiconductor material for one or both types of transistors.

In still further illustrative embodiments, a selective deposition of the additional silicon-containing semiconductor material may be accomplished without a hard mask by forming a strain-inducing semiconductor material in the other type of transistors, such as P-channel transistors, wherein a (111) plane may be provided as exposed surface areas of the strain-inducing semiconductor material. In this case, as is well known, the (111) crystalline plane may act as a deposition mask, since, during the selective epitaxial growth process, adhesion of the silicon-containing semiconductor material on the (111) planes may be substantially suppressed.

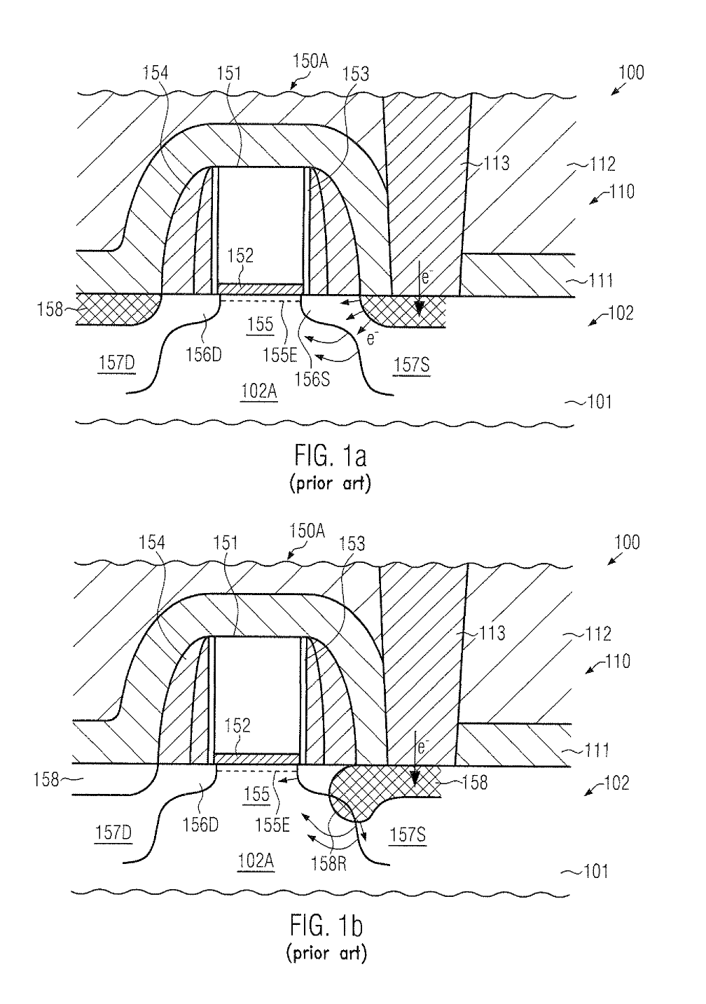

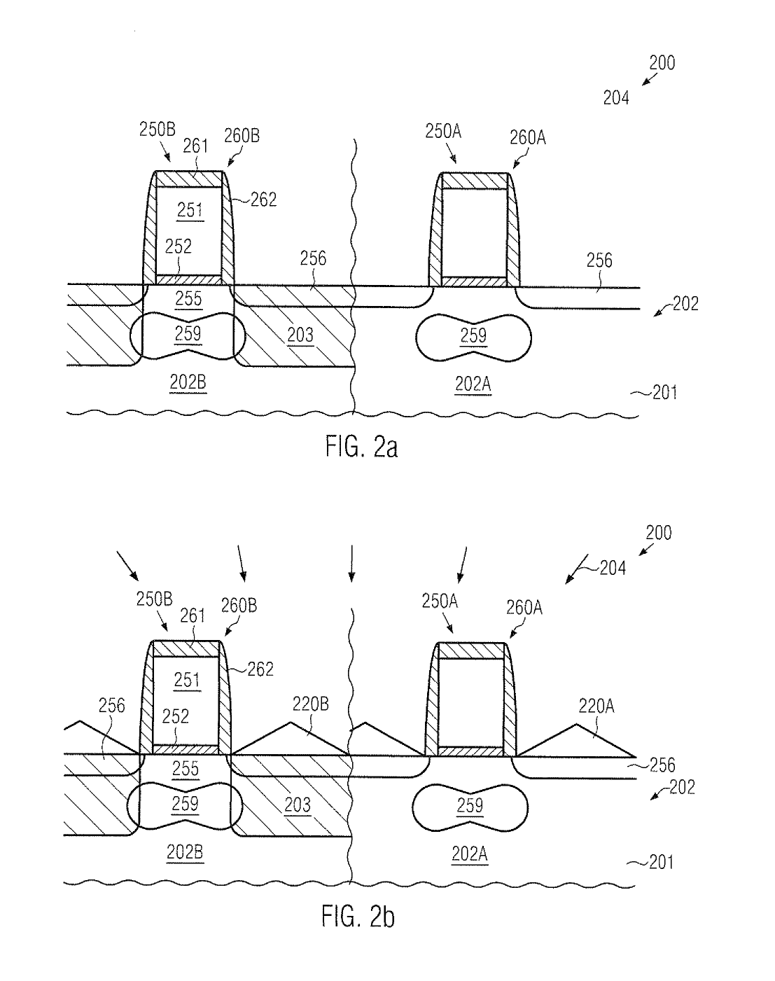

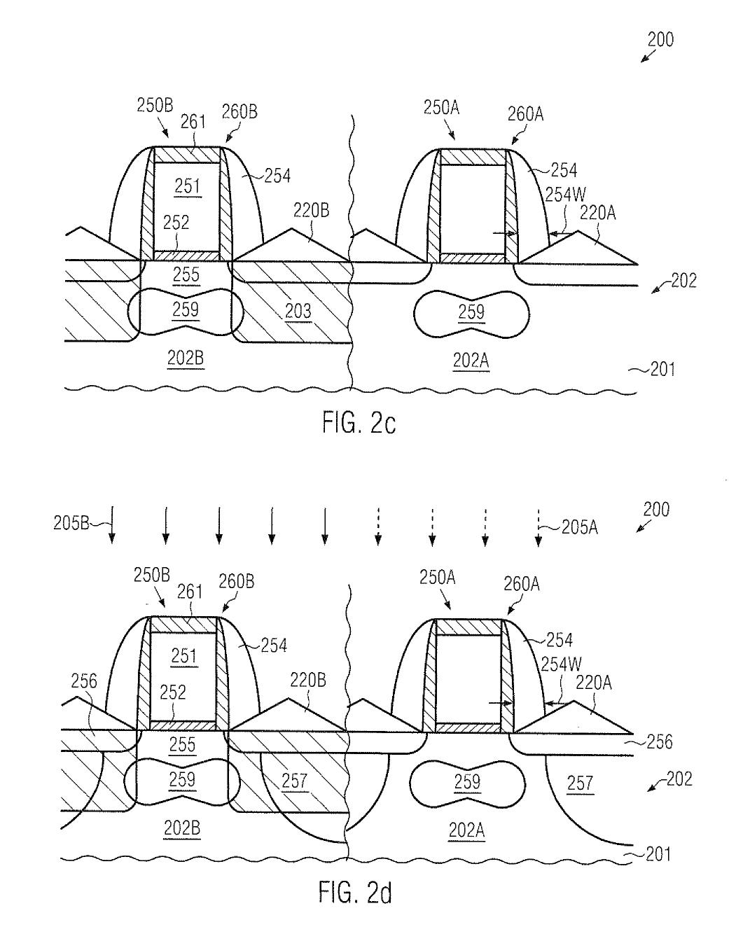

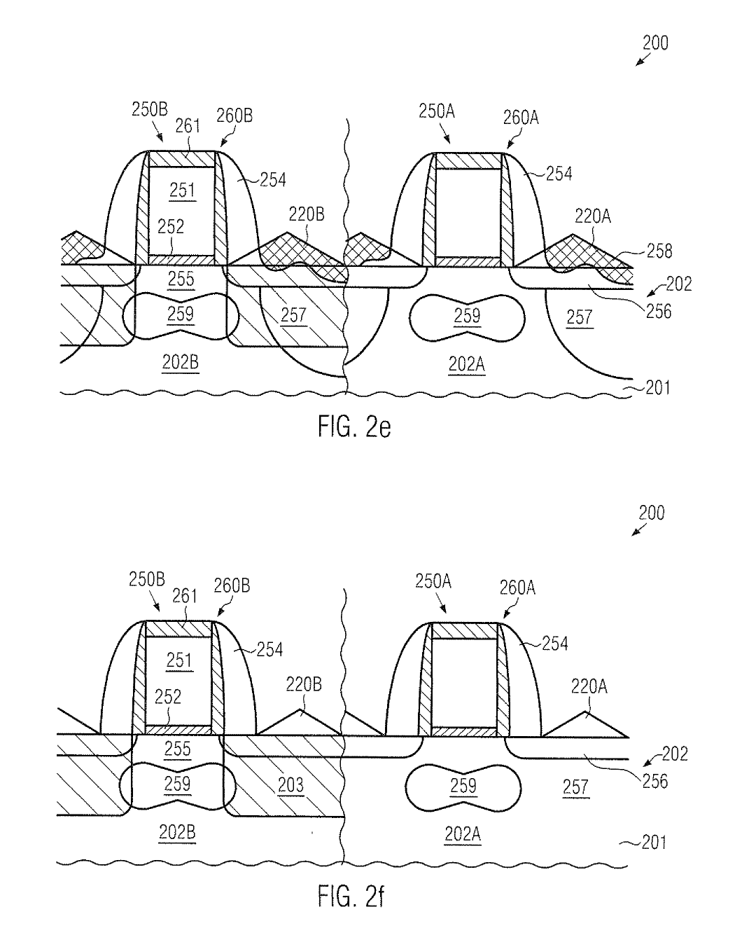

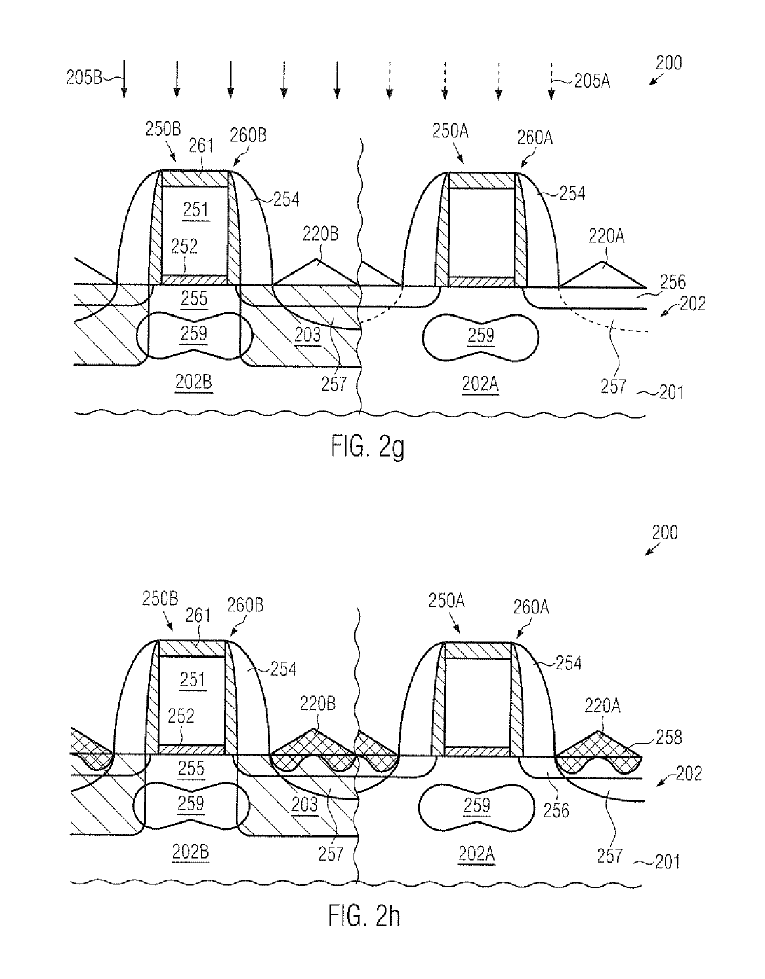

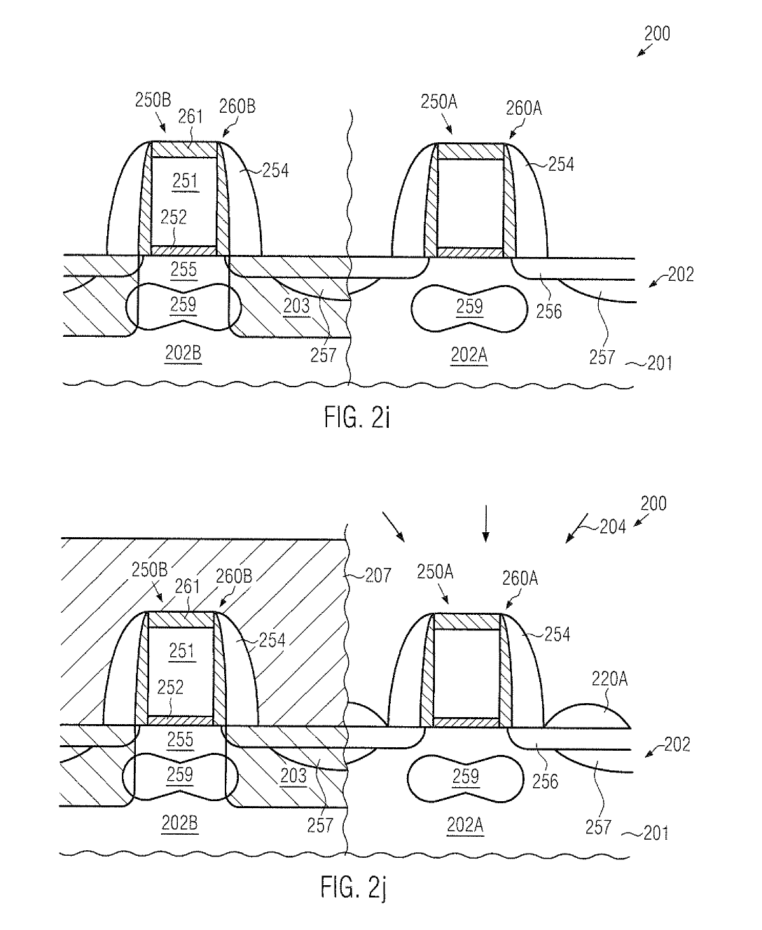

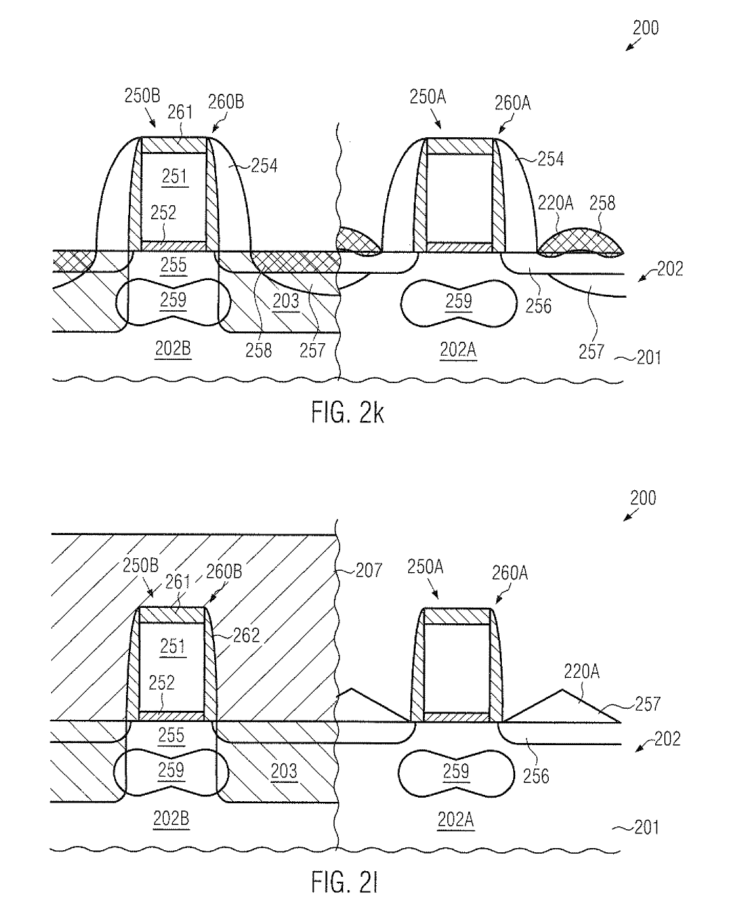

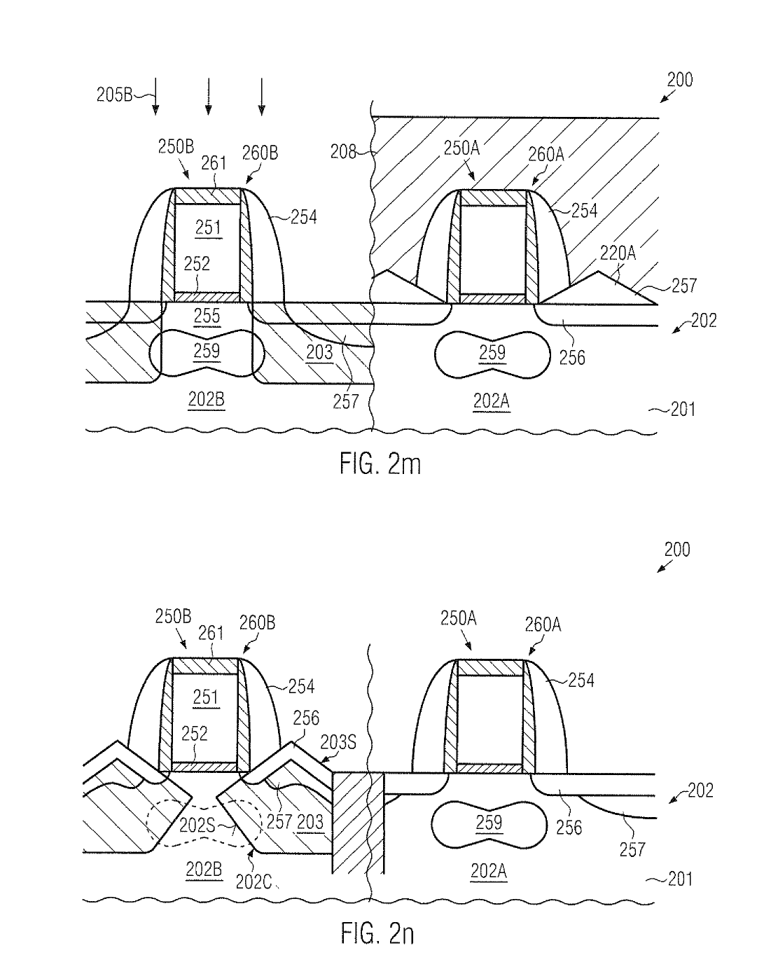

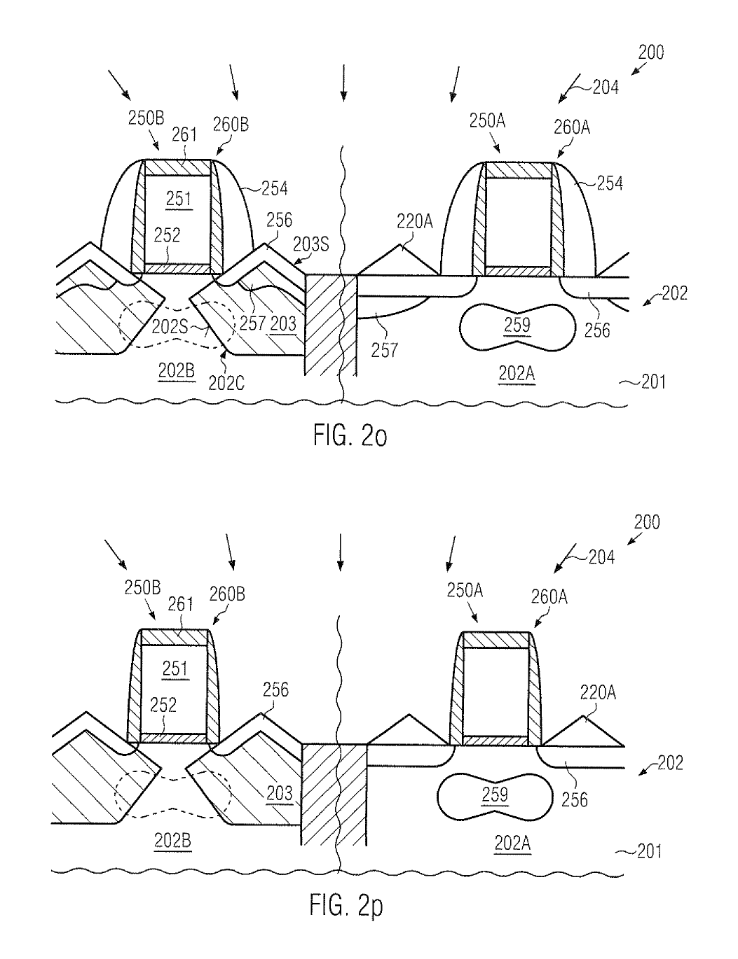

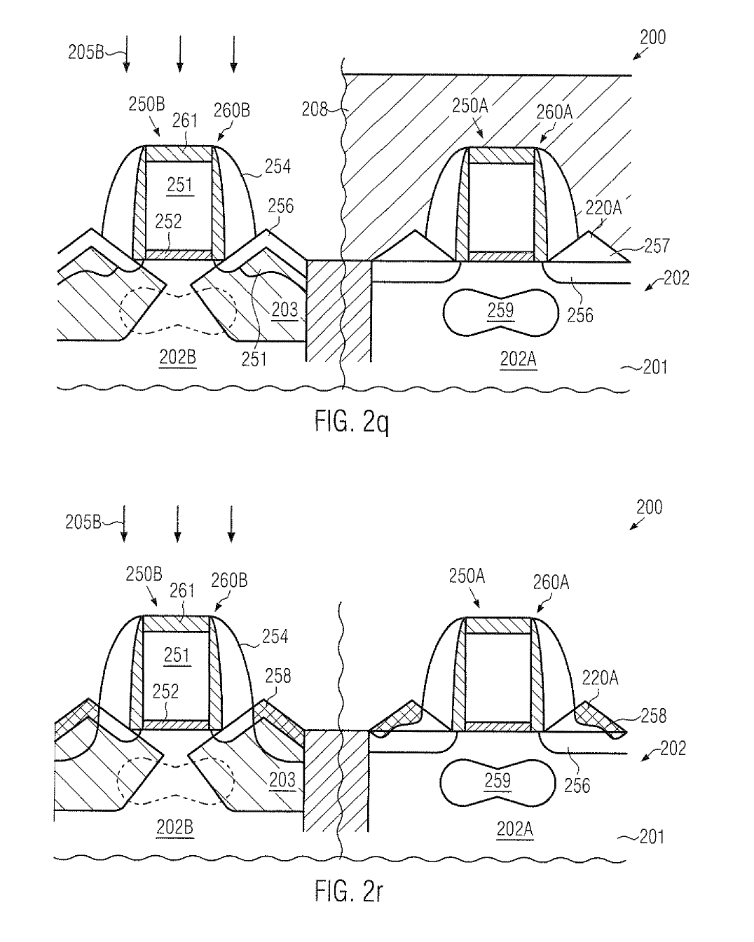

With reference to FIGS. 2a-2r, further illustrative embodiments will now be described in more detail, wherein reference may also be made to FIGS. 1a-1b, if appropriate.

FIG. 2a schematically illustrates a cross-sectional view of a semiconductor device 200 comprising a substrate 201 and a semiconductor layer 202, which may represent a silicon-based semiconductor material. It should be appreciated that the substrate 201 and the semiconductor layer 202 may represent a bulk configuration, in which the semiconductor layer 202 may be a portion of a crystalline material of the substrate 201. In other cases, a buried insulating layer (not shown) may be provided so as to “vertically” delineate the semiconductor layer 202 from the substrate 201. In this case, a silicon-on-insulator (SOI) configuration may be provided. The semiconductor layer 202 may comprise a first active region 202A of a first transistor 250A, such as an N-channel transistor. Moreover, a second active region 202B of a second transistor 250B, such as a P-channel transistor, may be formed in the semiconductor layer 202, wherein the active regions 202A, 202B may be laterally delineated by isolation structures (not shown), such as shallow trench isolations and the like. In the manufacturing stage shown, the transistor 250A may comprise a gate electrode structure 260A and the transistor 250B may comprise a gate electrode structure 260B. The gate electrode structures 260A, 260B may have substantially the same or a differing configuration, depending on the process history of the overall process strategy. Similarly, the gate electrode structures 260A, 260B may comprise a gate dielectric material 252, an electrode material 251 and a dielectric cap layer 261. Moreover, the gate electrode structures 260A, 260B may comprise a offset spacer structure 262, which may comprise a silicon liner (not shown), in combination with a silicon nitride material, and the like. It should be appreciated that the gate dielectric materials 252 may comprise sophisticated materials, for instance in the form of high-k dielectric materials, which are to be understood as dielectric materials having a dielectric constant of 10.0 and higher. For example, hafnium oxide-based materials, zirconium oxide-based materials and the like may frequently be used, possibly in combination with conventional dielectric materials, such as silicon dioxide, silicon oxynitride and the like. Furthermore, the electrode material 251 may comprise a metal species, if required, in combination with a semiconductor material, such as silicon and the like. Moreover, in some illustrative embodiments, one of the transistors 250A, 250B, for instance the P-channel transistor 250B, may comprise a strain-inducing semiconductor material 203 that is embedded in the active region 202B and which may have a strained state so as to induce a desired type of strain in a channel region 255 of the transistor 250B. For example, the material 203 may represent a silicon/germanium compound, which, when grown on a silicon material, may take on a strained state, thereby inducing a compressive strain component in the adjacent channel region 255. Furthermore, a moderate complex dopant profile may be established in the active regions 202A, 202B, for instance in the form of halo regions 259, which may be understood as doped areas having an increased dopant concentration, yet of the same conductivity type as the surrounding active regions 202A, 202B.

Furthermore, drain and source extension regions 256 may be formed in the active regions 202A, 202B according to the conductivity type of the respective transistors.

The semiconductor device 200 as shown in FIG. 2a may be formed on the basis of the following processes. After providing the active regions 202A, 202B corresponding to the basic conductivity type of the transistors 250A, 250B, which may be accomplished by providing isolation structures and incorporating appropriate dopant species on the basis of well-established masking regimes, the gate electrode structures 260A, 260B may be formed. For this purpose, any appropriate process technique may be applied, depending on the desired configuration of the gate electrode structures. For instance, conventional dielectrics may be grown and/or deposited, possibly in combination with high-k dielectric materials, followed by the deposition of appropriate electrode materials, such as metal-containing materials, silicon material and the like. Thereafter, the dielectric cap material 261 may be deposited and subsequently the resulting layer stack may be patterned based on sophisticated lithography and etch techniques. Next, the offset spacer structure 262 may be formed, for instance by oxidation and deposition of a spacer material, which may subsequently be etched, for instance selectively above the transistor 250B, when the strain-inducing semiconductor material 203 is to be formed therein. In this case, the spacer layer may be preserved above the transistor 250A. Thereafter, cavities may be etched into the active region 202B by using the cap material 261 and the spacers 262 as an etch mask. Thereafter, the strain-inducing semiconductor material 203 may be deposited into the cavities by performing a selective epitaxial growth technique. Next, the spacer layer may be selectively etched above the transistor 250A so as to form the spacer structure 262. In this manufacturing stage, the drain and source extension regions 256 and the halo regions 259 may be formed by applying an appropriate masking regime and implantation techniques. For example, the halo regions 259 may be formed by masking one of the transistors and performing a tilted implantation process. Similarly, the drain and source extension regions 256 for this type of transistor may be formed on the basis of the same implantation mask by incorporating a drain and source dopant species. Thereafter, a corresponding implantation sequence may be performed on the basis of an appropriate mask for the other transistor. If required, the dopant species in the active regions 202A, 202B may be activated by performing an anneal process.

Based on the configuration as shown in FIG. 2a, an additional silicon-containing semiconductor material may be formed in one or both of the active regions 202A, 202B, thereby providing a “raised” drain and source configuration for reliably embedding a metal silicide material, such as a nickel silicide material, in a highly doped semiconductor material. The point in time for forming an additional silicon-containing semiconductor material may depend on the overall process strategy, as will be explained in more detail later on.

FIG. 2b schematically illustrates the semiconductor device according to illustrative embodiments in which a silicon-containing semiconductor material 220A may be formed on the active region 202A and a silicon-containing semiconductor material 220B may be formed on the active region 202B in a common selective epitaxial growth process 204. During the growth process 204, well-established deposition recipes may be applied, in which process parameters, such as flow rates, gas composition of the deposition atmosphere, temperature and the like, are appropriately selected so as to obtain a growth on exposed crystalline surface areas, while a pronounced material deposition on dielectric surface areas is suppressed. Since the materials 220A, 220B are provided in the common deposition process 204, the incorporation of a dopant species may be avoided so as to not unduly affect the drain and source extension regions 256, which are of different conductivity types for the transistors 250A, 250B.

FIG. 2c schematically illustrates the semiconductor device 200 in a further advanced manufacturing stage in which a sidewall spacer structure 254 may be formed on sidewalls of the gate electrode structures 260A, 260B. To this end, any well-established process strategy may be applied, for instance, depositing an etch stop liner (not shown) in combination with a spacer material, which may be subsequently patterned by plasma assisted etch recipes. It should be appreciated that a width 254W of the spacer structures 254 may be adjusted with a superior degree of flexibility, for instance in reducing the overall width, since the additional semiconductor materials 220A, 220B may provide superior process margins when forming metal silicide areas therein, thereby significantly reducing the probability of creating silicide defects, as previously discussed with reference to FIG. 1b.

FIG. 2d schematically illustrates the semiconductor device 200 in a manufacturing phase in which drain and source regions 257 may be formed in the active regions 202A, 202B, thereby also incorporating a desired high dopant concentration in at least a portion of the additional semiconductor materials 220A, 220B. For this purpose, implantation processes 205A, 205B may be performed, based on appropriate implantation masks (not shown), in order to introduce the drain and source dopants into the materials 220A, 220B and, depending on the overall transistor configuration, into deeper lying areas of the active regions 202A, 202B. In the embodiment shown, the drain and source regions 257 may extend vertically beyond the extension regions 256, while, in other cases, the drain and source regions 257 may be substantially restricted to the semiconductor material 220A, 220B and the drain and source extension regions 256, if extremely shallow PN junctions are required. It should be appreciated that appropriate process parameters for the implantation processes 205A, 205B may be readily established on the basis of simulation, experiments and the like.

FIG. 2e schematically illustrates the semiconductor device 200 in a further advanced manufacturing stage. As illustrated, metal silicide regions 258 are provided, at least in a portion of the additional silicon-containing semiconductor material 220A, 220B, wherein the material 258 may be reliably maintained within the extension region 256 and/or the drain and source regions 257. The metal silicide 258, for instance, in one illustrative embodiment, in the form of a nickel silicide material, may be formed on the basis of well-established silicidation techniques by depositing a refractory metal and initiating a chemical reaction by performing a heat treatment. Due to the additional material 220A, 220B, the metal diffusion may take place within the drain and source regions 257 and/or the extension regions 256, even if a reduced width of the spacer structure 254 may be selected, for instance with respect to providing a superior overall dopant profile and/or for reducing a lateral offset of an interlayer dielectric material still to be formed above the transistors 250A, 250B. Consequently, critical dimensions of the transistor 250A, 250B may be reduced without increasing the probability of creating metal silicide defects. Consequently, the overall series resistance of the resulting transistor elements may be reduced without contributing to a pronounced increase of yield losses.

FIG. 2f schematically illustrates the semiconductor device 200 according to still further illustrative embodiments in which the additional semiconductor materials 220A, 220B are laterally offset from the gate electrode structures 260A, 260B by the spacer structure 254. For this purpose, starting with the configuration as shown in FIG. 2a, the spacer structure 254 may be formed after providing the drain and source extension regions 256, which may be accomplished in accordance with any appropriate spacer technique. Thereafter, a selective epitaxial growth process may be performed, in which the gate electrode structures 260A, 260B and the spacer structures 254 are used as a growth mask.

FIG. 2g schematically illustrates the device 200 during an implantation sequence including the processes 205A, 205B on the basis of appropriate implantation masks (not shown) in order to form the drain and source regions 257 and also to incorporate a desired high dopant concentration into the regions 220A, 220B. Consequently, during the implantation processes 205A, 205B, the drain and source dopant species may be incorporated in the entire volume of the materials 220A, 220B. With respect to adapting any process parameters, the same criteria may apply as previously explained.

FIG. 2h schematically illustrates the semiconductor device 200 with the metal silicide 258 formed in the drain and source regions 257. Consequently, any interface of the metal silicide 258 with a semiconductor material may be represented by a highly doped semiconductor material, thereby reducing the barrier and thus the series resistance, as previously explained.

FIG. 2i schematically illustrates the semiconductor device 200 according to still further illustrative embodiments in which the drain and source regions 257 may be formed in the active regions 202A, 202B on the basis of the spacer structure 254. For this purpose, starting from the configuration as shown in FIG. 2a, the spacer structure 254 may be formed in accordance with any appropriate process technique, as described above. Thereafter, an implantation sequence may be performed so as to incorporate the drain and source dopant species into the active regions 202A, 202B by using corresponding implantation masks (not shown), as discussed above. Thereafter, if required, an anneal process may be performed so as to activate the dopants and re-crystallize implantation-induced damage, which may be advantageous for providing a superior “template” material for the subsequent selective epitaxial growth process.

FIG. 2j schematically illustrates the semiconductor device 200 in a further advanced manufacturing stage in which one of the transistors 250A, 250B, such as the transistor 250B, may be covered by a growth mask 207, while the transistor 250A is exposed to the deposition ambient of the selective epitaxial growth process 204. For this purpose, the growth mask 207 may be deposited in the form of any appropriate material, such as silicon dioxide, silicon nitride, possibly in combination with an oxide liner, amorphous carbon and the like, which may then be patterned so as to cover one of the transistors 250A, 250B. Thereafter, the deposition process 204 may be performed in order to provide the silicon-containing semiconductor material 220A, which may have incorporated therein a desired high dopant concentration of a drain and source dopant species of the transistor 250A. To this end, an appropriate precursor gas including the desired dopant species may be incorporated into the deposition atmosphere of the process 204, which may be accomplished on the basis of well-established process recipes. In this case, any appropriate dopant concentration may be provided in the material 220A as is considered advantageous for forming a metal silicide therein and reducing the corresponding silicide/semiconductor barrier. For example, the material 220A may be deposited with a higher dopant concentration compared to the dopant concentration in the drain and source regions 257 of the transistor 250A. Thereafter, the growth mask 207 may be removed, for instance, by any appropriate etch technique. It should be appreciated that the growth mask 207 may be provided in the form of a substantial conformal layer with a specific thickness of several nanometers in order to enhance the removal of the growth mask 207 without unduly affecting other device areas, such as isolation structures and the like.

FIG. 2k schematically illustrates the semiconductor device 200 in a further advanced manufacturing stage in which metal silicide 258 may be formed in the additional semiconductor material 220A, thereby providing the superior process margins, while, in the transistor 250B, the metal silicide 258 may be formed in the drain and source regions 257, without providing an epitaxially grown semiconductor material. It should be appreciated that, generally, the situation in the transistor 250B may be less critical, for instance by forming the strain-inducing material 203 with some extra height (not shown), thereby also providing superior process margins in forming the metal silicide 258. In other cases, the material 203 may have a different diffusion behavior during the silicidation process, which may result in less critical process conditions.

It should be appreciated that the above-described process sequence may be performed on the basis of the transistor 250B, i.e., the transistor 250A may be masked during the selective epitaxial growth process and a highly doped additional semiconductor material may be selectively formed on the transistor 250B. In still other illustrative embodiments, the above-described process sequence may be repeated by covering the transistor 250A having formed therein the additional semiconductor material 220A by providing an appropriate growth mask and selectively depositing a further silicon-containing semiconductor material with a desired high dopant concentration. Thereafter, the corresponding growth mask may be removed and the metal silicide 258 may be formed on the basis of a highly doped additional silicon-containing semiconductor material for both transistors 250A, 250B.

FIG. 21 schematically illustrates the semiconductor device 200 according to still further illustrative embodiments in which, starting from the configuration as shown in FIG. 2a, the growth mask 207 may be formed so as to cover one of the transistors 250A, 250B, such as the transistor 250B, prior to forming drain and source regions and prior to forming a corresponding sidewall spacer structure. Consequently, after forming the growth mask 207, a selective epitaxial growth process may be performed in order to provide the silicon-containing semiconductor material 220A for the transistor 250A, which may comprise an appropriate dopant species so as to act as the drain and source regions 257. Thus, the selectively grown material 220A may appropriately connect to the drain and source extension regions 256 in the transistor 250A, while the growth mask 207 may suppress the incorporation of any undesired dopant species for the transistor 250B. Next, the growth mask 207 may be removed by any appropriate etch processes, for instance based on hydrofluoric acid, if comprised of silicon dioxide material, and the like. It should also be appreciated that an additional etch mask may be formed above the transistor 250A, such as a resist mask, if the etch selectivity of the growth mask 207 is considered inappropriate with respect to, for instance, any material of the transistor 250A, of isolation structures and the like. In other cases, material, such as amorphous carbon, may be efficiently removed on the basis of an oxygen plasma, substantially without affecting other exposed surface areas. Thereafter, the processing may be continued by forming a sidewall spacer structure.

FIG. 2m schematically illustrates the semiconductor device 200 in a further advanced manufacturing stage in which the spacer structure 254 is formed on sidewalls of the gate electrode structures 260A, 260B, while an implantation mask 208 may cover the transistor 250A during the implantation process 205B. Thus, during the process 205B, the drain and source regions 257 of the transistor 250B may be provided, while any additional implantation processes for the transistor 250A may not be required, thereby reducing the overall process complexity. Hence, upon removing the mask 208 and performing an anneal process for activating the dopants of the drain and source regions 257 of the transistor 250B, the metal silicide may be formed in accordance with process techniques described above, thereby obtaining a configuration that is similar to the device of FIG. 2k, wherein, however, the drain and source regions 257 of the transistor 250A may be restricted to the additional semiconductor material 220A.

It should be appreciated that, in other illustrative embodiments, the drain and source regions 257 of the transistor 250B may be formed, in addition or alternatively to the drain and source regions of the transistor 250A, by providing an additional silicon-containing semiconductor material having incorporated therein a desired dopant concentration. For this purpose, an appropriate growth mask has to be provided, as is also discussed above. In this case, any additional implantation processes for forming the drain and source regions of any one of the transistors 250A, 250B or of both of these transistors may be avoided, which may result in an overall superior dopant profile.

FIG. 2n schematically illustrates the semiconductor device 200 according to further illustrative embodiments in which the additional silicon-containing semiconductor material may be selectively applied in one transistor without requiring a deposition mask. As illustrated, the transistors 250A, 250B may comprise a spacer structure 254 and the drain and source regions 257. Moreover, the transistor 250B may comprise the strain-inducing material 203 with a specific configuration that may act as a “growth” mask. As illustrated, the strain-inducing semiconductor alloy 203, such as a silicon/germanium alloy, may be formed in a “sigma” shaped cavity 202C, wherein corresponding sidewalls 202S may be represented by (111) silicon planes. This may be accomplished by forming the cavities 202C on the basis of an appropriate etch chemistry that provides a crystallographically anisotropic etch behavior. For instance, a plurality of reactive base materials, such as TMAH (tetra methyl ammonium hydroxide) may efficiently etch silicon material, wherein the (111) plane may have a significantly reduced etch rate compared to other silicon planes, such as the (100) or (110) planes or any physically equivalent planes, upon epitaxially growing the strain-inducing semiconductor material 203. A corresponding “sigma” shaped configuration may be obtained upon overgrowing the cavities 202C, thereby finally obtaining (111) planes as surface areas 203S, which may suppress the deposition of any further crystalline material, thereby providing a self-limiting deposition behavior. It is well known that (111) planes in silicon and similar materials, such as silicon/germanium mixtures, may significantly reduce the deposition rate compared to other crystallographic orientations. Consequently, the surface area 203S may represent a growth mask during the deposition of an additional silicon material, which may thus be selectively formed on the exposed active region 202A of the transistor 250A.

FIG. 2o schematically illustrates the semiconductor device 200 during the selective epitaxial growth process 204, in which the silicon containing material 220A may be selectively deposited in the transistor 250A in the form of a highly doped semiconductor material, while the strain-inducing sigma shaped material 203 in the transistor 250B may efficiently suppress any deposition of the material 220A.

Thereafter, further processing may be continued by forming metal silicide regions, wherein the additional material 220A in a highly doped configuration may provide superior process margins, while, in the transistor 250B, the sigma shaped material 203 may per se provide a significantly reduced probability of creating metal silicide defects.

FIG. 2p schematically illustrates the semiconductor device 200 according to still further illustrative embodiments in which the device 200 is exposed to the deposition ambient 204 prior to forming a spacer structure required for forming drain and source regions, at least in the transistor 250B. In this case, if desired, the silicon-containing material 220A may be deposited as a doped material with a dopant concentration that is appropriate for forming the drain and source regions of the transistor 250A. As discussed before, a deposition of the material 220A in the transistor 250B may be suppressed due to the sigma shaped configuration of the strain-inducing material 203.

FIG. 2q schematically illustrates the device 200 in a further advanced manufacturing stage. As illustrated, the transistor 250A comprising the material 220A in the form of the drain and source regions 257 may be covered by an implantation mask 208, while the transistor 250B comprising the sidewall spacer structure 254 may be exposed to the implantation process 205B in order to incorporate the dopant species for the drain and source regions 257. With respect to forming the sidewall spacer structure 254 and performing the implantation process 205B, the same criteria may apply as previously explained.

FIG. 2r schematically illustrates the semiconductor device 200 with the metal silicide 258 formed in the transistors 250A, 250B. Thus, the metal silicide 258 may be embedded in the material 220A and possibly in the extension region 256 so that any silicide/semiconductor interface is formed on the basis of a highly doped semiconductor material. Similarly, the metal silicide 258 in the transistor 250B may also be reliably embedded in a highly doped semiconductor material due to the sigma configuration of the strain-inducing semiconductor material 203.

As a result, the present disclosure provides semiconductor devices and manufacturing techniques in which the probability of creating metal silicide defects may be reduced by providing an additional silicon-containing semiconductor material after the formation of drain and source extension regions and halo regions, at least for one type of transistor. It should be appreciated that a metal silicide may also be formed in the gate electrode structures by removing any dielectric cap materials after growing the additional silicon-containing semi-conductor material in the drain and source regions. Hence, the principles disclosed herein may be applied to any desired configuration of gate electrode structures and any process strategy for forming these gate electrode structures.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming drain and source extension regions in a semiconductor region by using a gate electrode structure as an implantation mask;
forming a silicon-containing semiconductor material above said drain and source extension regions on said semiconductor region laterally adjacent to said gate electrode structure;
forming drain and source regions in at least a portion of said silicon-containing semiconductor material; and
forming a metal silicide in said silicon-containing semiconductor material.

2. The method of claim 1, wherein said metal silicide comprises nickel.

3. The method of claim 1, wherein forming said metal silicide comprises forming a spacer structure on sidewalls of said gate electrode structure and using said spacer structure as a mask.

4. The method of claim 3, wherein said spacer structure is formed prior to forming said silicon-containing semiconductor material and after forming said drain and source extension regions.

5. The method of claim 3, wherein said spacer structure is formed after forming said silicon-containing semiconductor material.

6. The method of claim 5, wherein forming said drain and source regions comprises incorporating a drain/source dopant species while depositing said silicon-containing semiconductor material.

7. The method of claim 1, wherein forming said silicon-containing semiconductor material comprises incorporating a dopant species while depositing said silicon-containing semiconductor material.

8. The method of claim 1, wherein said drain and source regions are part of an N-channel transistor.

9. The method of claim 1, further comprising forming a strain-inducing semiconductor material in said semiconductor region prior to forming said drain and source extension regions.

10. A method, comprising:
forming a first gate electrode structure of a P-channel transistor above a first active region;
forming a second gate electrode structure of an N-channel transistor above a second active region;
forming drain and source extension regions in said first and second active regions;
forming a silicon-containing semiconductor material above said drain and source extension regions of at least one of said P-channel transistor and said N-channel transistor;
forming drain and source regions of said P-channel transistor and said N-channel transistor; and
forming a metal silicide at least in a portion of said silicon-containing semiconductor material.

11. The method of claim 10, wherein forming said silicon-containing semiconductor material comprises forming said silicon-containing semiconductor material above said drain and source regions of said P-channel transistor and said N-channel transistor.

12. The method of claim 10, wherein forming said silicon-containing semiconductor material comprises performing a selective epitaxial growth process while masking one of said first and second active regions.

13. The method of claim 10, further comprising forming a spacer structure on sidewalls of said first and second gate electrode structures, wherein said silicon-containing semiconductor material is formed prior to forming said spacer structure.

14. The method of claim 10, further comprising forming a spacer structure on sidewalls of said first and second gate electrode structures, wherein said silicon-containing semiconductor material is formed after forming said spacer structure.

15. The method of claim 10, wherein forming said drain and source regions of said P-channel transistor and said N-channel transistor comprises incorporating a drain and source dopant species into at least a portion of said silicon-containing semiconductor material while depositing said at least a portion of said silicon-containing semiconductor material.

16. The method of claim 10, wherein forming said silicon-containing semiconductor material comprises selectively depositing said silicon-containing semiconductor material above one of said first and second active regions and incorporating a dopant species while selectively depositing said silicon-containing semiconductor material.

17. The method of claim 10, further comprising forming a strain-inducing semiconductor material in one of said P-channel transistor and said N-channel transistor and using said strain-inducing semiconductor material as a growth mask when depositing said silicon-containing semiconductor material.

18. The method of claim 17, wherein said strain-inducing semiconductor material is formed in said P-channel transistor.

19. A semiconductor device, comprising:
a P-channel transistor formed in and above a first active region;
an N-channel transistor formed in and above a second active region;
a doped silicon-containing semiconductor material formed on said second active region so as to provide a raised drain and source configuration; and
a nickel silicide embedded in said doped silicon-containing semiconductor material.

20. The semiconductor device of claim 19, further comprising a strain-inducing semiconductor material formed in said first active region.
